(19) United States
(12) Patent Application Publication
(10) Pub. No.: US 2026/0173491 A1
(43) Pub. Date: Jun. 18, 2026

(54) SEMICONDUCTOR DEVICE WITH MULTIPLE THRESHOLD VOLTAGES AND METHODS OF FORMING

(71) Applicant: Taiwan Semiconductor Manufacturing Co., Ltd., Hsinchu (TW)

(72) Inventors: Yao-Teng Chuang, Hsinchu (TW); Tsung-Da Lin, Hsinchu (TW); Chi On Chui, Hsinchu (TW)

(21) Appl. No.: 19/098,162

(22) Filed: Apr. 2, 2025

Related U.S. Application Data
(60) Provisional application No. 63/734,898, filed on Dec. 17, 2024.

(51) Int. Cl. H10D 64/68; H01L 21/28; H10D 30/00; H10D 30/01; H10D 62/10; H10D 64/01; H10D 64/27

(52) U.S. Cl. CPC H10D 64/685; H10D 30/014; H10D 30/502; H10D 64/0134; H10D 64/017; H10D 64/513; H10D 64/691; H10D 62/121

(57) ABSTRACT

During the formation of the gate structures of a semiconductor device, dipole layers comprising different dipole-forming elements and/or having different thicknesses are formed on the gate dielectric material in different regions of the semiconductor device. A dipole drive-in process (e.g., a thermal process) is performed next to drive the dipole-forming elements of the dipole layers into the gate dielectric material. The dipole-forming elements driven into the gate dielectric material form dipoles with certain element of the gate dielectric material. The dipoles are used to adjust the threshold voltages of the gate structures, and to achieve different threshold voltages for gate structures formed in the different regions of the semiconductor device.

### PRIORITY CLAIM AND CROSS-REFERENCE

This application claims priority to U.S. Provisional Patent Application No. 63/734,898, filed Dec. 17, 2024 and entitled “Multi-Dipole Incorporation for Device Multi-Threshold Voltage,” which application is hereby incorporated by reference in its entirety.

### BACKGROUND

Semiconductor devices are used in a variety of electronic applications, such as, for example, personal computers, cell phones, digital cameras, and other electronic equipment. Semiconductor devices are typically fabricated by depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (NSFET) device in a three-dimensional view, in accordance with some embodiments.

FIGS. 2, 3A, 3B, 4A, 4B, 5A, 5B, 5C, 6A, 6B, 6C, 7A, 7B, 7C, 8A, 8B, 9A, 9B, 9C, 10, 11, 12, 13, 14, 15A, 15B, 16A, 16B, 17A, and 17B illustrate cross-sectional views of a nanostructure field-effect transistor (NSFET) device at various stages of manufacturing, in accordance with an embodiment.

FIGS. 18, 19, 20, 21, 22, 23, and 24 illustrate processing steps for forming different dipoles in a gate dielectric material, in accordance with an embodiment.

FIGS. 25, 26, 27, 28, 29, 30, 31, and 32 illustrate processing steps for forming different dipoles in a gate dielectric material, in accordance with another embodiment.

FIGS. 33A and 33B together illustrate a flow chart of a method of forming a semiconductor device, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact.

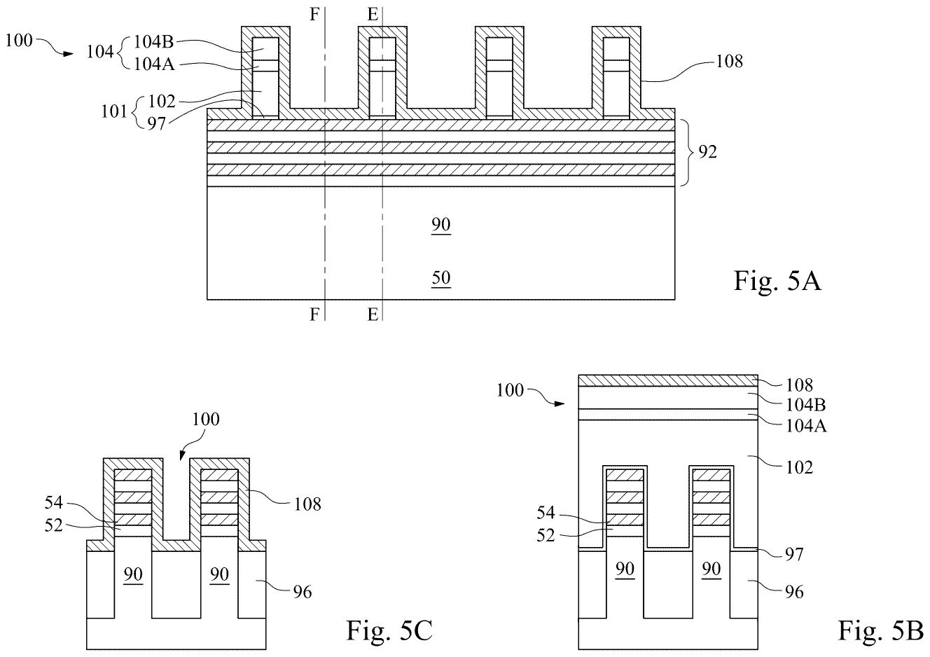

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Throughout the discussion herein, unless otherwise described, the same or similar reference numeral in different figures refer to the same or similar component formed by a same or similar formation process using a same or similar material(s). In addition, figures with the same numeral but different alphabets (e.g., FIGS. 5A-5C) illustrate different views of the same device at the same stage of processing.

Various embodiments of the present disclosure are discussed in the context of forming a nanostructure field-effect transistor (NSFET) device, with the understanding that the disclosed methods for adjusting the threshold voltages of gate stacks may also be applied to other types of semiconductor devices, such as fin field-effect transistor (FinFET) devices, planar devices, or the like.

In some embodiments, during the formation of the gate structures of a semiconductor device, dipole layers comprising different dipole-forming elements and/or having different thicknesses are formed on the gate dielectric material in different regions of the semiconductor device. A dipole drive-in process (e.g., a thermal process) is performed next to drive the dipole-forming elements of the dipole layers into the gate dielectric material. The dipole-forming elements driven into the gate dielectric material form dipoles with certain element of the gate dielectric material. The dipoles are used to adjust the threshold voltages of the gate structures, and to achieve different threshold voltages for gate structures formed in the different regions of the semiconductor device.

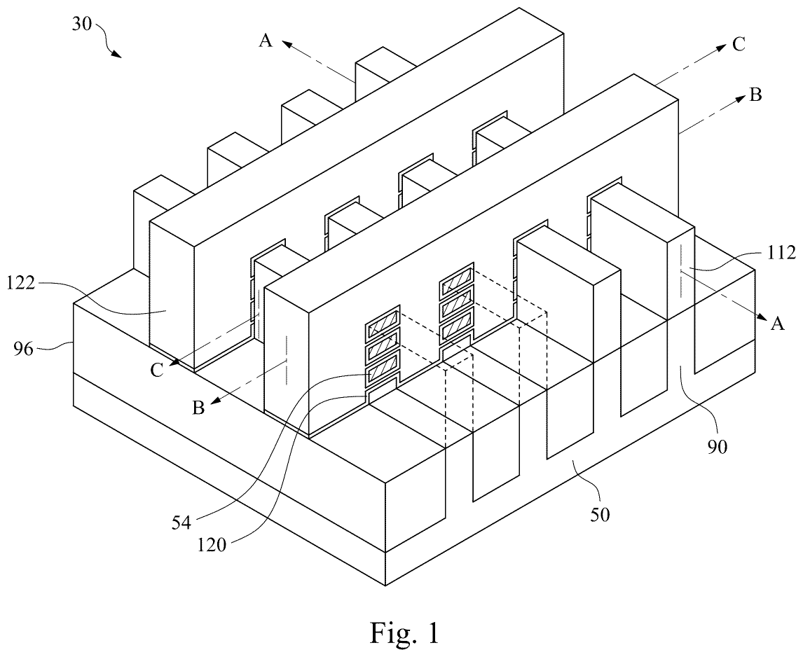

FIG. 1 illustrates an example of a nanostructure field-effect transistor (NSFET) device 30 in a three-dimensional view, in accordance with some embodiments. The NSFET device 30 comprises semiconductor fins 90 (also referred to as fins) protruding above a substrate 50. Gate electrodes 122 (e.g., metal gates) are disposed over the fins, and source/drain regions 112 are formed on opposing sides of the gate electrodes 122. A plurality of nanostructures 54 (e.g., nanowires, or nanosheets) are formed over the fins 90 and between source/drain regions 112. Isolation regions 96 are formed on opposing sides of the fins 90. A gate dielectric layer 120 is formed around the nanostructures 54. Gate electrodes 122 are over and around the gate dielectric layer 120.

FIG. 1 further illustrates reference cross-sections that are used in later figures. Cross-section A-A is along a longitudinal axis of the fin 90 and is in a direction of, for example, a current flow between the source/drain regions 112 of the NSFET device. Cross-section B-B is perpendicular to cross-section A-A and is along a longitudinal axis of the gate electrode 122. Cross-section C-C is parallel to cross-section B-B and extends through source/drain regions 112 of the NSFET device. Subsequent figures may refer to these reference cross-sections for clarity.

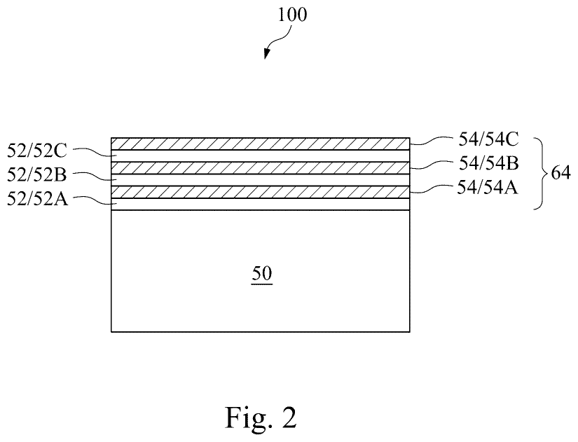

FIGS. 2, 3A, 3B, 4A, 4B, 5A, 5B, 5C, 6A, 6B, 6C, 7A, 7B, 7C, 8A, 8B, 9A, 9B, 9C, 10, 11, 12, 13, 14, 15A, 15B, 16A, 16B, 17A, and 17B illustrate cross-sectional views of a nanostructure field-effect transistor (NSFET) device 100 at various stages of manufacturing, in accordance with an embodiment.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon substrate or a glass substrate. Other substrates, such as a multi-layered or gradient substrate may also be used. In some embodiments, the semiconductor material of the substrate 50 includes silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

A multi-layer stack 64 is formed on the substrate 50. The multi-layer stack 64 includes alternating layers of a first semiconductor material 52 and a second semiconductor material 54. In FIG. 2, layers formed by the first semiconductor material 52 are labeled as 52A, 52B, and 52C, and layers formed by the second semiconductor material 54 are labeled as 54A, 54B, and 54C. The number of layers formed by the first and the second semiconductor materials illustrated in FIG. 2 are merely non-limiting examples. Other numbers of layers are also possible and are fully intended to be included within the scope of the present disclosure.

In some embodiments, the first semiconductor material 52 is an epitaxial material appropriate for forming channel regions of p-type FETs, such as silicon germanium (SiₓGe₁₋ₓ, where x can be in the range of 0 to 1), and the second semiconductor material 54 is an epitaxial material appropriate for forming channel regions of n-type FETs, such as silicon. In some embodiments, the second semiconductor material 54 (e.g., silicon) may be used to form both n-type or p-type FETs, and the first semiconductor material 52 is used as a sacrificial material that is removed later. The multi-layer stack 64 (which may also be referred to as an epitaxial material stack) will be patterned to form the channel regions of an NSFET in subsequent processing. For example, the multi-layer stack 64 may be patterned and etched to form nanostructures (e.g., nanosheets or nanowires), with the channel regions of the resulting NSFET including nanostructures that are vertically stacked over a fin, and with each nanostructure extending parallel to a major upper surface of the substrate.

The multi-layer stack 64 may be formed by an epitaxial growth process, which may be performed in a growth chamber. During the epitaxial growth process, the growth chamber is cyclically exposed to a first set of precursors for selectively growing the first semiconductor material 52, and then exposed to a second set of precursors for selectively growing the second semiconductor material 54, in some embodiments. The first set of precursors includes precursors for the first semiconductor material (e.g., silicon germanium), and the second set of precursors includes precursors for the second semiconductor material (e.g., silicon). In some embodiments, the first set of precursors includes a silicon precursor (e.g., silane) and a germanium precursor (e.g., a germane), and the second set of precursors includes the silicon precursor but omits the germanium precursor. The epitaxial growth process may thus include continuously enabling a flow of the silicon precursor to the growth chamber, and then cyclically: (1) enabling a flow of the germanium precursor to the growth chamber when growing the first semiconductor material 52; and (2) disabling the flow of the germanium precursor to the growth chamber when growing the second semiconductor material 54. The cyclical exposure may be repeated until a target number of layers is formed.

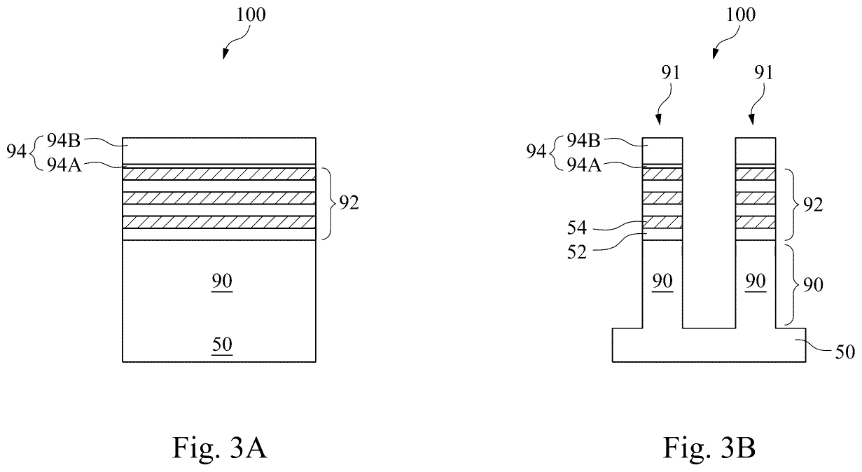

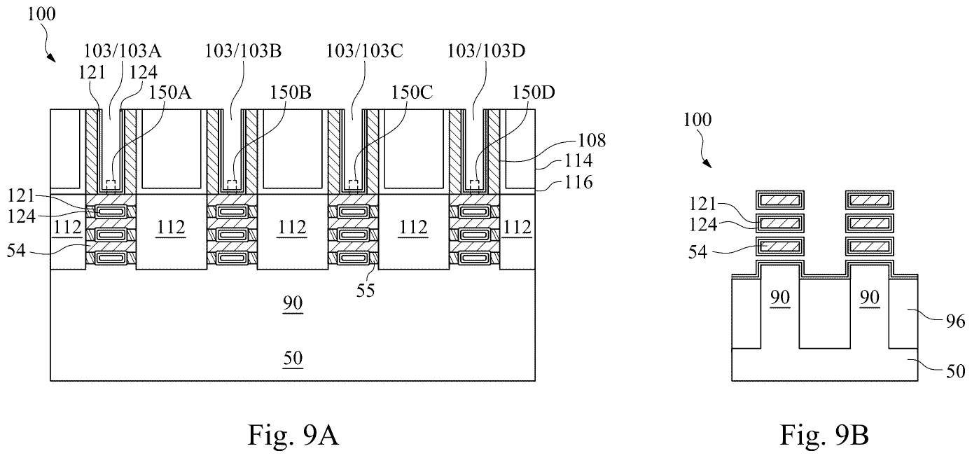

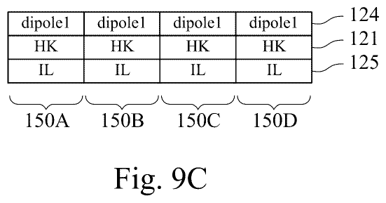

FIGS. 3A, 3B, 4A, 4B, 5A, 5B, 5C, 6A, 6B, 6C, 7A, 7B, 7C, 8A, 8B, 9A, 9B, 9C, 10, 11, 12, 13, 14, 15A, 15B, 16A, 16B, 17A, and 17B illustrate cross-sectional views of the NSFET device 100 at subsequent stages of manufacturing, in accordance with an embodiment. FIGS. 3A, 4A, 5A, 6A, 7A, 8A, 9A, 16A, and 17A are cross-sectional views along cross-section A-A in FIG. 1. FIGS. 3B, 4B, 5B, 6B, 7B, 8B, 9B, 16B, and 17B are cross-sectional views along cross-section B-B in FIG. 1. FIGS. 5C, 6C, and 7C are cross-sectional views along cross-section C-C in FIG. 1. FIGS. 9C, 10, 11, 12, 13, 14, 15A, and 15B are zoomed-in views of portions of the semiconductor device. The number of fins and the number of gate structures illustrated in the figures are merely non-limiting examples, it should be appreciated that other numbers of fins and other numbers of gate structures may also be formed.

In FIGS. 3A and 3B, fin structures 91 are formed protruding above the substrate 50. Each of the fin structures 91 includes a semiconductor fin 90 (also referred to as a fin) and a layer stack 92 overlying the semiconductor fin 90. The layer stack 92 and the semiconductor fin 90 may be formed by etching trenches in the multi-layer stack 64 and the substrate 50, respectively. The layer stack 92 and the semiconductor fin 90 may be formed by a same etching process.

The fin structures 91 may be patterned by any suitable method. For example, the fin structures 91 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. In an embodiment, a sacrificial layer is formed over a substrate and patterned using a photolithography process. Spacers are formed alongside the patterned sacrificial layer using a self-aligned process. The sacrificial layer is then removed, and the remaining spacers are then be used to pattern, e.g., the fin structures 91.

In some embodiments, the remaining spacers are used to pattern a mask 94, which is then used to pattern the fin structures 91. The mask 94 may be a single layer mask, or may be a multilayer mask such as a multilayer mask that includes a first mask layer 94A and a second mask layer 94B. The first mask layer 94A and second mask layer 94B may each be formed from a dielectric material such as silicon oxide, silicon nitride, a combination thereof, or the like, and may be deposited or thermally grown according to suitable techniques. The first mask layer 94A and second mask layer 94B are different materials having a high etching selectivity. For example, the first mask layer 94A may be silicon oxide, and the second mask layer 94B may be silicon nitride. The mask 94 may be formed by patterning the first mask layer 94A and the second mask layer 94B using any acceptable etching process. The mask 94 may then be used as an etching mask to etch the substrate 50 and the multi-layer stack 64. The etching may be any acceptable etch process, such as a reactive ion etch (RIE), neutral beam etch (NBE), the like, or a combination thereof. The etching is an anisotropic etching process, in some embodiments. After the etching process, the patterned multi-layer stack 64 forms the layer stacks 92, and the patterned portion of the substrate 50 forms the fins 90, as illustrated in FIGS. 3A and 3B. The unetched lower portion of the substrate 50 is referred to as substrate 50 in FIGS. 3A and 3B (and subsequent figures). Therefore, in the illustrated embodiment, the layer stack 92 also includes alternating layers of the first semiconductor material 52 and the second semiconductor material 54, and the fin 90 is formed of a same material (e.g., silicon) as the substrate 50.

The fins 90 and the layer stacks 92 in FIG. 3B are illustrated to have substantially perpendicular sidewalls (e.g. perpendicular to the major upper surface of the substrate 50). The shapes of the fins 90 and the layer stacks 92 illustrated in FIG. 3B are merely non-limiting examples. The fins 90 and the layer stacks 92 may have sloped sidewalls (e.g., having trapezoidal cross-sections). The sloped sidewalls may be formed due to the properties of the anisotropic etching process used to form the fins 90 and the layer stacks 92. For example, the etching capability of the anisotropic etching process may decrease along the downward vertical direction of FIG. 3B, which may result in the sloped sidewalls for the fins 90 and the layer stacks 92.

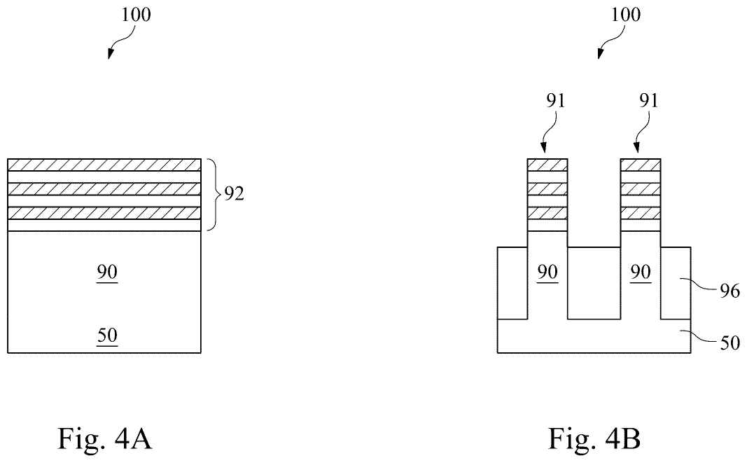

Next, in FIGS. 4A and 4B, shallow trench isolation (STI) regions 96 are formed over the substrate 50 and on opposing sides of the fin structures 91. As an example to form the STI regions 96, an insulation material may be formed over the substrate 50. The insulation material may be an oxide such as silicon oxide, a nitride, the like, or a combination thereof, and may be formed by a high-density plasma chemical vapor deposition (HDP-CVD), a flowable CVD (FCVD) (e.g., a CVD-based material deposition in a remote plasma system and post curing to make it convert to another material, such as an oxide), the like, or a combination thereof. Other insulation materials formed by any acceptable process may be used. In the illustrated embodiment, the insulation material is silicon oxide formed by an FCVD process. An anneal process may be performed after the insulation material is formed.

In some embodiments, the insulation material is formed such that excess insulation material covers the fin structures 91. In some embodiments, a liner is first formed along surfaces of the substrate 50 and fin structures 91, and a fill material, such as those discussed above is formed over the liner. In some embodiments, the liner is omitted.

Next, a removal process is applied to the insulation material to remove excess insulation material over the fin structures 91. The removal process also removes the mask 94, in the illustrated embodiment. In some embodiments, a planarization process such as a chemical mechanical planarization (CMP) process, an etch back process, combinations thereof, or the like, may be utilized. The planarization process exposes the layer stacks 92 such that top surfaces of the layer stacks 92 and the insulation material are level after the planarization process is completed. Next, the insulation material is recessed to form the STI regions 96. The insulation material is recessed such that the layer stacks 92 protrude from between neighboring STI regions 96. Top portions of the semiconductor fins 90 may also protrude from between neighboring STI regions 96. Further, the top surfaces of the STI regions 96 may have a flat surface as illustrated, a convex surface, a concave surface (such as dishing), or a combination thereof. The top surfaces of the STI regions 96 may be formed flat, convex, and/or concave by an appropriate etch. The STI regions 96 may be recessed using an acceptable etching process, such as one that is selective to the material of the insulation material (e.g., etches the material of the insulation material at a faster rate than other materials, such as the materials of the fin 90 and the layer stack 92). For example, a chemical oxide removal with a suitable etchant such as dilute hydrofluoric (dHF) acid may be used.

Next, in FIGS. 5A-5C, a dummy dielectric layer 97 is formed over the layer stack 92 and over the STI regions 96. The dummy dielectric layer 97 may be, for example, silicon oxide, silicon nitride, a combination thereof, or the like, and may be deposited or thermally grown according to acceptable techniques.

Next, dummy gates 102 are formed over the fin structures 91. To form the dummy gates 102, a dummy gate layer may be formed over the dummy dielectric layer 97. The dummy gate layer may be deposited over the dummy dielectric layer 97 and then planarized, such as by CMP. The dummy gate layer may be any suitable material, such as amorphous silicon, polycrystalline-silicon (polysilicon), poly-crystalline silicon-germanium (poly-SiGe), or the like. The dummy gate layer may be deposited by physical vapor deposition (PVD), CVD, sputter deposition, or other techniques known and used in the art. The dummy gate layer may be made of other materials that have a high etching selectivity from the STI regions 96.

Masks 104 are then formed over the dummy gate layer. The masks 104 may be formed from silicon nitride, silicon oxynitride, combinations thereof, or the like, and may be patterned using acceptable photolithography and etching techniques. In the illustrated embodiment, the mask 104 includes a first mask layer 104A (e.g., a silicon oxide layer) and a second mask layer 104B (e.g., a silicon nitride layer). The pattern of the masks 104 is then transferred to the dummy gate layer by an acceptable etching technique to form the dummy gates 102, and then transferred to the dummy dielectric layer by acceptable etching technique to form dummy gate dielectrics 97. The dummy gates 102 cover respective channel regions of the layer stacks 92. The pattern of the masks 104 may be used to physically separate each of the dummy gates 102 from adjacent dummy gates. The dummy gates 102 may also have a lengthwise direction substantially perpendicular to the lengthwise direction of the fin structures 91. The dummy gates 102 and the dummy gate dielectrics 97 are collectively referred to as dummy gate structures 101.

Next, a gate spacer layer 108 is formed by conformally depositing an insulating material over the layer stacks 92, the STI regions 96, and the dummy gates 102. The insulating material may be silicon nitride, silicon carbonitride, a combination thereof, or the like. In some embodiments, the gate spacer layer 108 includes multiple sublayers. For example, a first sublayer (sometimes referred to as a gate seal spacer layer) may be formed by thermal oxidation or a deposition, and a second sublayer (sometimes referred to as a main gate spacer layer) may be conformally deposited on the first sublayer.

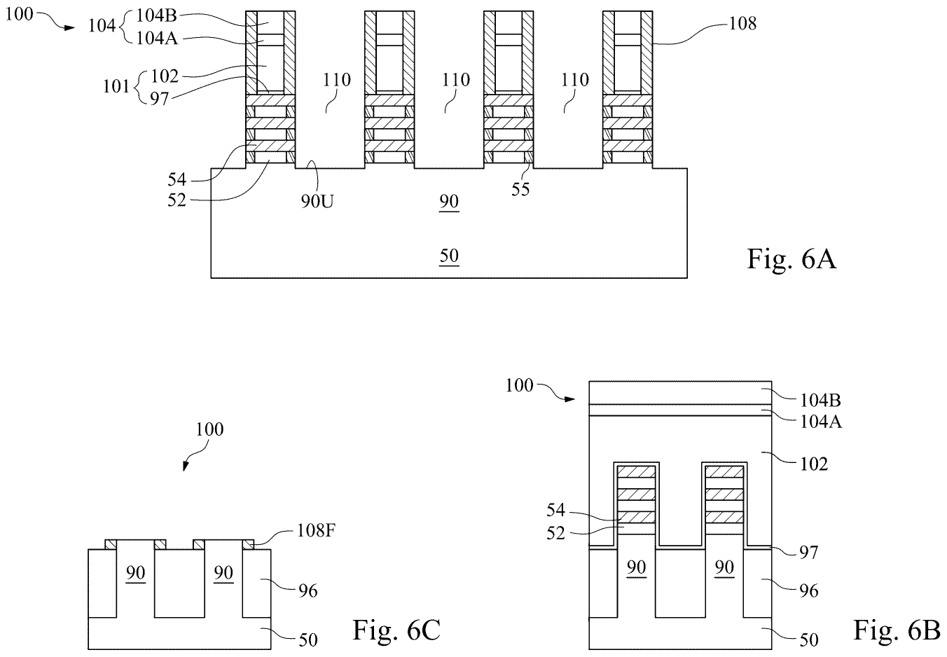

FIGS. 5B and 5C illustrate cross-sectional views of the NSFET device 100 in FIG. 5A along cross-sections E-E and F-F in FIG. 5A, respectively. The cross-sections E-E and F-F correspond to cross-sections B-B and C-C in FIG. 1, respectively. Unless otherwise specified, subsequent figures with alphabets A, B and C (e.g., FIGS. 6A, 6B, and 6C) illustrate cross-sectional views along the same cross-sections as FIGS. 5A, 5B, and 5C, respectively.

Next, in FIGS. 6A-6C, the gate spacer layer 108 is etched by an anisotropic etching process to form gate spacers 108. The anisotropic etching process may remove horizontal portions of the gate spacer layer 108 (e.g., portions over the STI regions 96 and the dummy gates structures 101), with remaining vertical portions of the gate spacer layer 108 (e.g., portions along sidewalls of the dummy gate structures 101) forming the gate spacers 108.

After the formation of the gate spacers 108, implantation for lightly doped source/drain (LDD) regions (not shown) may be performed. Appropriate type (e.g., p-type or n-type) impurities may be implanted into the exposed layer stacks 92 and/or fins 90. The n-type impurities may be any suitable n-type impurities, such as phosphorus, arsenic, antimony, or the like, and the p-type impurities may be any suitable p-type impurities, such as boron, BF₂, indium, or the like. The lightly doped source/drain regions may have a concentration of impurities between about 1E15/cm³ and about 1E16/cm³. An anneal process may be used to activate the implanted impurities.

Next, openings 110 (which may also be referred to as recesses, or source/drain openings) are formed in the layer stacks 92. The openings 110 may extend through the layer stacks 92 and into the fins 90. The openings 110 may be formed by an anisotropic etching process using, e.g., the dummy gate structures 101 and the gate spacers 108 as an etching mask.

After the openings 110 are formed, a selective etching process is performed to recess end portions of the first semiconductor material 52 exposed by the openings 110 without substantially attacking the second semiconductor material 54. After the selective etching process, recesses (also referred to as sidewall recesses) are formed in the first semiconductor material 52 at locations where the removed end portions used to be.

Next, an inner spacer layer is formed (e.g., conformally) in the openings 110 to line sidewalls and bottoms of the openings 110. The inner spacer layer also fills the sidewall recesses of the first semiconductor material 52 formed by the previous selective etching process. The inner spacer layer may be a suitable dielectric material, such as silicon carbonitride (SiCN), silicon oxycarbonitride (SiOCN), or the like, and may be formed by a suitable deposition method such as PVD, CVD, atomic layer deposition (ALD), or the like. Next, an etching process, such as an anisotropic etching process, is performed to remove portions of the inner spacer layer disposed outside the sidewall recesses of the first semiconductor material 52. The remaining portions of the inner spacer layer (e.g., portions disposed inside the sidewall recesses of the first semiconductor material 52) form inner spacers 55. As illustrated in FIG. 6A, the openings 110 expose sidewalls of the second semiconductor material 54, and expose upper surfaces 90U of the fins 90 at the bottoms of the openings 110.

In the example of FIG. 6C, portions of the gate spacer layer 108 disposed on the upper surface of the STI regions 96 between neighboring fins 90 are completely removed by the anisotropic etching process used for forming the gate spacers 108. Remaining portions of the gate spacer layer 108 along the sidewalls of the fins 90 form fin spacers 108F. In FIG. 6C, the upper surface of the STI regions 96 between neighboring fins 90 is illustrated as a flat surface as a non-limiting example. The upper surface of the STI regions 96 between neighboring fins 90 may be curved (e.g., concave), e.g., due to the anisotropic etching process removing upper portions of the STI regions 96.

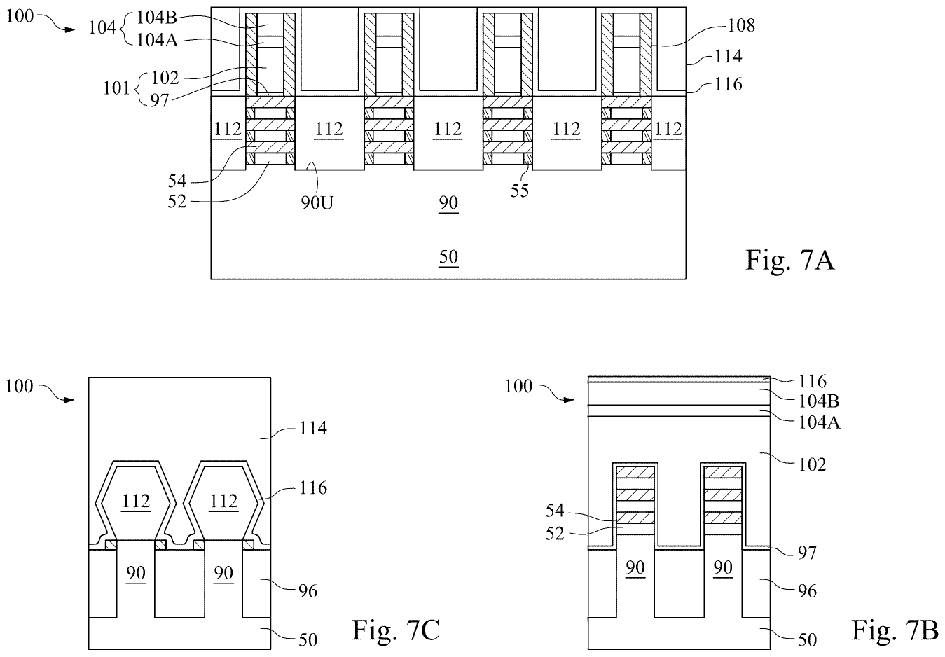

Next, in FIG. 7A-7C, source/drain regions 112 are formed in the openings 110. In the discussion herein, source/drain region(s) may refer to a source or a drain, individually or collectively dependent upon the context. In the illustrated embodiment, the source/drain regions 112 are formed of an epitaxial material(s), and therefore, may also be referred to as epitaxial source/drain regions 112. In some embodiments, the epitaxial source/drain regions 112 are formed in the openings 110 to exert stress in the respective channel regions of the NSFET device formed, thereby improving performance. In some embodiments, the epitaxial source/drain regions 112 are formed such that the dummy gate 102 is disposed between respective neighboring pairs of the epitaxial source/drain regions 112. In some embodiments, the gate spacers 108 are used to separate the epitaxial source/drain regions 112 from the dummy gates 102 by an appropriate lateral distance so that the epitaxial source/drain regions 112 do not short out subsequently formed replacement gate structures of the resulting NSFET device.

The epitaxial source/drain regions 112 are epitaxially grown in the openings 110, in some embodiments. The epitaxial source/drain regions 112 may include any acceptable material, such as appropriate for n-type or p-type device. For example, when n-type devices are formed, the epitaxial source/drain regions 112 may include materials exerting a tensile strain in the channel regions, such as silicon, SiC, SiCP, SiP, or the like. Likewise, when p-type devices are formed, the epitaxial source/drain regions 112 may include materials exerting a compressive strain in the channel regions, such as SiGe, SiGeB, Ge, GeSn, or the like. The epitaxial source/drain regions 112 may have surfaces raised from respective surfaces of the fins 90 and may have facets.

The epitaxial source/drain regions 112 and/or the fins 90 may be implanted with a dopant (e.g., n-type impurities or p-type impurities), similar to the process previously discussed for forming lightly-doped source/drain regions, followed by an anneal. The source/drain regions may have an impurity concentration (may also be referred to as a dopant concentration) of between about 1E19/cm³ and about 1E21/cm³. The n-type and/or p-type impurities for source/drain regions may be any of the impurities previously discussed. In some embodiments, the epitaxial source/drain regions 112 may be in situ doped during growth.

As a result of the epitaxy processes used to form the epitaxial source/drain regions 112, upper surfaces of the epitaxial source/drain regions 112 have facets which expand laterally outward beyond sidewalls of the fins 90. In the illustrated embodiment, adjacent epitaxial source/drain regions 112 remain separated (see FIG. 7C) after the epitaxy process is completed. In other embodiments, these facets cause adjacent epitaxial source/drain regions 112 to merge together.

Next, a contact etch stop layer (CESL) 116 is formed (e.g., conformally) over the source/drain regions 112 and over the dummy gate structures 101, and a first inter-layer dielectric (ILD) 114 is then deposited over the CESL 116. The CESL 116 is formed of a material having a different etch rate than the first ILD 114, and may be formed of silicon nitride using PECVD, although other dielectric materials such as silicon oxide, silicon oxynitride, combinations thereof, or the like, and alternative techniques of forming the CESL 116, such as low-pressure CVD (LPCVD), PVD, or the like, could alternatively be used.

The first ILD 114 may be formed of a dielectric material, and may be deposited by any suitable method, such as CVD, PECVD, or FCVD. Dielectric materials for the first ILD 114 may include silicon oxide, Phospho-Silicate Glass (PSG), Boro-Silicate Glass (BSG), Boron-Doped Phospho-Silicate Glass (BPSG), undoped Silicate Glass (USG), or the like. Other insulation materials formed by any acceptable process may be used.

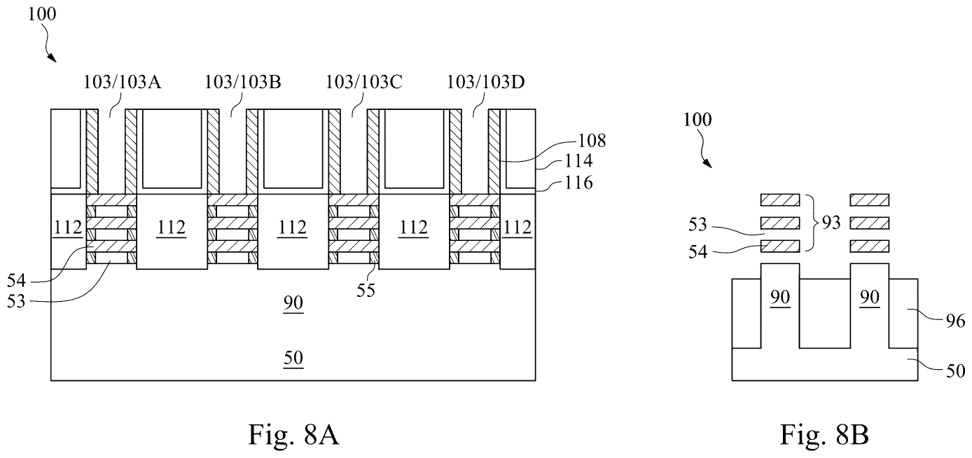

Next, in FIGS. 8A and 8B, the dummy gates 102 and the dummy gate dielectrics 97 are removed. Note that for simplicity, the cross-sectional views along cross-section F-F illustrated in FIG. 5A are not illustrated for processing steps hereinafter, because such cross-sectional views are the same as or similar to FIG. 7C, or may be easily modified from FIG. 7C (e.g., by adding additional layers/features formed after the formation of the first ILD 114).

To remove the dummy gates 102, a planarization process, such as a CMP, is performed to level the top surfaces of the first ILD 114 and the CESL 116 with the top surfaces of the dummy gates 102 and the gate spacers 108. The planarization process may also remove the masks 104 (see FIG. 7A) on the dummy gates 102, and portions of the gate spacers 108 along sidewalls of the masks 104. After the planarization process, top surfaces of the dummy gates 102, the gate spacers 108, the CESL 116, and the first ILD 114 are level. Accordingly, the top surfaces of the dummy gates 102 are exposed through the first ILD 114.

Next, the dummy gates 102 are removed in an etching step(s), so that recesses 103 (also referred to as gate trenches) are formed. In some embodiments, the dummy gates 102 are removed by an anisotropic dry etch process. For example, the etching process may include a dry etch process using reaction gas(es) that selectively etch the dummy gates 102 without etching the first ILD 114 or the gate spacers 108. During the removal of the dummy gates 102, the dummy gate dielectrics 97 may be used as an etch stop layer when the dummy gates 102 are etched. The dummy gate dielectrics 97 may then be removed after the removal of the dummy gates 102. An etching process, such as an isotropic etching process, may be performed to remove the dummy gate dielectrics 97. As illustrated in FIGS. 8A and 8B, the recesses 103 expose the channel regions of the NSFET device 100. The channel regions are disposed between neighboring pairs of the epitaxial source/drain regions 112.

Next, the first semiconductor material 52 (e.g., portions exposed by the recesses 103) is removed to release the second semiconductor material 54. After the first semiconductor material 52 is removed, the second semiconductor material 54 (e.g., portions underlying the dummy gates 102 before the dummy gates 102 are removed) forms a plurality of nanostructures 54. Each nanostructure 54 may be referred to as a channel region or a channel layer. The nanostructures 54 may be collectively referred to as the channel regions 93 or the channel layers 93 of the NSFET device 100 formed. As illustrated in FIGS. 8A and 8B, gaps 53 (e.g., empty spaces) are formed between the nanostructures 54 by the removal of the first semiconductor material 52. In some embodiments, the nanostructures 54 are nanosheets or nanowires, depending on, e.g., the dimensions (e.g., size and/or aspect ratio) of the nanostructures 54.

In some embodiments, the first semiconductor material 52 is removed by a selective etching process using an etchant that is selective to (e.g., having a higher etch rate for) the first semiconductor material 52, such that the first semiconductor material 52 is removed without substantially attacking the second semiconductor material 54. In some embodiments, an isotropic etching process is performed to remove the first semiconductor material 52. The isotropic etching process is performed using an etching gas, and optionally, a carrier gas. The etching gas comprises F₂ and HF, and the carrier gas may be an inert gas such as Ar, He, N₂, combinations thereof, or the like, in some embodiments.

Next, in FIGS. 9A and 9B, a gate dielectric material 121 and a dipole layer 124 are formed in the recesses 103. The gate dielectric material 121 is deposited conformally in the recesses 103, such as on the top surfaces and the sidewalls of the semiconductor fins 90, and on sidewalls of the gate spacers 108. The gate dielectric material 121 may also be formed on the top surface of the first ILD 114. Notably, the gate dielectric material 121 is formed to wrap around the nanostructures 54. In accordance with some embodiments, the gate dielectric material 121 comprises silicon oxide, silicon nitride, or multilayers thereof. In some embodiments, the gate dielectric material 121 is formed of a high-K dielectric material, and in these embodiments, the gate dielectric material 121 may have a dielectric constant (also referred to as K value) greater than about 7.0, and may include a metal oxide or a silicate of Hf, Al, Zr, La, Mg, Ba, Ti, or Pb, or combinations thereof. The formation methods of the gate dielectric material 121 may include Molecular-Beam Deposition (MBD), ALD, PECVD, and the like.

In some embodiments, an interfacial layer 125 (not shown in FIG. 9A but illustrated in FIG. 9C) is formed around the nanostructures 54 before the gate dielectric material 121 is formed. The interfacial layer 125 may be, e.g., an oxide of the material of the nanostructure 54, and may be deposited or thermally grown on the nanostructures 54. In some embodiments, the interfacial layer 125 is omitted.

Next, the dipole layer 124 is formed conformally over and around the gate dielectric material 121. In some embodiments, the dipole layer 124 is a layer of a dipole material, and therefore, may also be referred to as a dipole material 124, or a dipole film 124. In some embodiments, the dipole layer 124 comprises a dipole-forming element, such as a dipole-forming metal. The dipole layer 124 may be, e.g., an oxide of an n-type dipole-forming metal such as lanthanum (La), yttrium (Y), scandium (Sc), strontium (Sr), or the like, or may be an oxide of a p-type dipole-forming metal such as aluminum (Al), zinc (Zn), gallium (Ga), or the like. Examples of the material used to form the dipole layer 124 include La₂O₃, Y₂O₃, Sc₂O₃, SrO, Al₂O₃, ZnO, and GaO. The dipole layer 124 may be formed using a suitable formation method such as CVD, ALD, or the like. A thickness of the dipole layer 124 may be between about 1 angstrom and about 10 angstroms, as an example.

In subsequent processing, atoms of the dipole-forming element (e.g., a dipole-forming metal) of the dipole layer 124 are driven into (e.g., diffuses into) the gate dielectric material 121 by a dipole drive-in process (e.g., a thermal process), and form dipoles with atoms of certain element (e.g., oxygen atoms) of the gate dielectric material 121. In some embodiments, during the dipole drive-in process, atoms of the dipole-forming metal diffuse into the gate dielectric material 121, and substitute for other atoms in the gate dielectric material 121 (e.g., HfO₂) or occupy interstitial positions. In some embodiments, the incorporated atoms of the dipole-forming metal form bonds with oxygen atoms in the gate dielectric material 121 to form dipoles, and the metal-oxygen bonds (e.g., La—O bonds, Y—O bonds, Sc—O bonds, Sr—O bonds, Al—O bonds, Zn—O bonds, or Ga—O bonds) create dipole moments within the gate dielectric material 121. In some embodiments, the dipoles formed in the gate dielectric material 121 create an electric field due to their charge separation. This electric field modifies the local work function difference between the gate stack and channel region. As a result, the dipoles shift the energy bands in the semiconductor, and/or create an additional voltage drop across the gate stack.

Depending on the orientations of the dipoles formed in the gate dielectric material 121, the dipoles can either increase or decrease the threshold voltage of the transistor (may also be referred to as the threshold voltage of the gate stack) formed. In other words, the dipoles formed in the gate dielectric material 121 may be used to tune the threshold voltage of the gate stack. In some embodiments, dipoles formed in the gate dielectric material 121 by the p-type dipole-forming metal (also referred to as p-type dipoles) can increase the threshold voltage of an n-type transistor, or decrease the threshold voltage of a p-type transistor. Similarly, dipoles formed in the gate dielectric material 121 by the n-type dipole-forming metal (also referred to as n-type dipoles) can decrease the threshold voltage of an n-type transistor, or increase the threshold voltage of a p-type transistor, in some embodiments. Note that the terms “n-type” and “p-type,” when used in the context of transistors (e.g., n-type transistor, p-type transistors), refer to the conductivity type of the transistor. In contrast, in the context of dipoles (e.g., n-type dipole-forming element, p-type dipole-forming element, n-type dipoles, p-type dipoles), the terms “n-type” and “p-type” refer to the effect of the dipoles on the threshold voltages of the transistors, such as making transistors more “p-like” or “n-like” in terms of their threshold voltage characteristics.

In semiconductor device design, it may be advantageous to have different threshold voltages for difference transistors in the same semiconductor device. Various embodiment methods for achieving different threshold voltages for different transistors in a semiconductor device are disclosed herein. The different threshold voltages for different transistors may be achieved by forming, in the different transistors, different dipole layers (e.g., dipole layers comprising different dipole-forming elements) and/or dipole layers with the same dipole-forming element but different thicknesses, on the gate dielectric material 121, then driving the dipole-forming element(s) into the gate dielectric material 121. The dipole layers are then removed after the dipole drive-in process. In addition, or alternatively, the different threshold voltages may also be achieved by modifying the condition (e.g., temperature, and/or duration) of the dipole drive-in process (e.g., a thermal process). The various approaches discussed above may be combined in any suitable manner to result in different types and/or different densities for the dipole-forming element(s) driven into the gate dielectric material 121, so as to achieve different threshold voltages for different transistors. More details are discussed hereinafter.

FIG. 9C illustrates a zoomed-in view of regions 150A, 150B, 150C, and 150D in FIG. 9A. The regions 150A, 150B, 150C, and 150D are regions above the topmost nanostructure 54 in gate trenches 103A, 103B, 103C, and 103D, respectively. In other words, the gate trenches 103A, 103B, 103C, and 103D correspond to regions 150A, 150B, 150C, and 150D, respectively. In the discussion hereinafter, the regions 150A, 150B, 150C, and 150D may be used interchangeably with gate trenches 103A, 103B, 103C, and 103D, respectively. For example, a dipole layer 124 formed in the gate trenches 103A, 103B, 103C, and 103D may also be said to be formed in regions 150A, 150B, 150C, and 150D. As another example, a portion of a dipole layer removed from the gate trench 103A may also be said to be removed from the region 150A.

In FIG. 9C, the regions 150A, 150B, 150C, and 150D are illustrated in FIG. 9C as being immediately adjacent (e.g., contacting) to each other, with the understanding that the regions 150A, 150B, 150C, and 150D are spaced apart from each other (see, e.g., FIG. 9A). The regions 150A, 150B, 150C, and 150D may correspond to different device regions (e.g., logic regions, memory regions) of the NSFET device 100. Although the regions 150A, 150B, 150C, and 150D are illustrated as being located in gate trenches next to each other in FIG. 9A, the regions 150A, 150B, 150C, and 150D may be in gate trenches far apart from each other (e.g., with other gate trenches in between). In addition, although the regions 150A, 150B, 150C, and 150D are illustrated as being located in gate trenches over a same fin 90, the regions 150A, 150B, 150C, and 150D may be located in gate trenches over different fins 90, as skilled artisans readily appreciate.

FIG. 9C illustrates the gate dielectric material 121 and the dipole layer 124 formed on the gate dielectric material 121. In addition, FIG. 9C illustrates the interfacial layer 125 under the gate dielectric material 121 (e.g., between the gate dielectric material 121 and the nanostructures 54). Note that in the example of FIGS. 9A-9C, the dipole layer 124 is formed in all of the regions 150A, 150B, 150C, and 150D (e.g., in all of the gate trenches 103A, 103B, 103C, and 103D).

The dipole layer 124 (and the subsequently formed dipole layers such as 126 and 128) may comprise any type (e.g., n-type or p-type) of dipole-forming element, regardless of the conductivity type of the transistor formed. For example, in the gate trench of an n-type (or p-type) transistor, the dipole layer 124 comprising an n-type dipole-forming element or a p-type dipole-forming element may be formed. As discussed above, the n-type dipole-forming element or the p-type dipole-forming metal forms n-type dipoles or p-type dipoles in the gate dielectric material 121 to tune (e.g., increase or decrease) the threshold voltage of the gate stack formed.

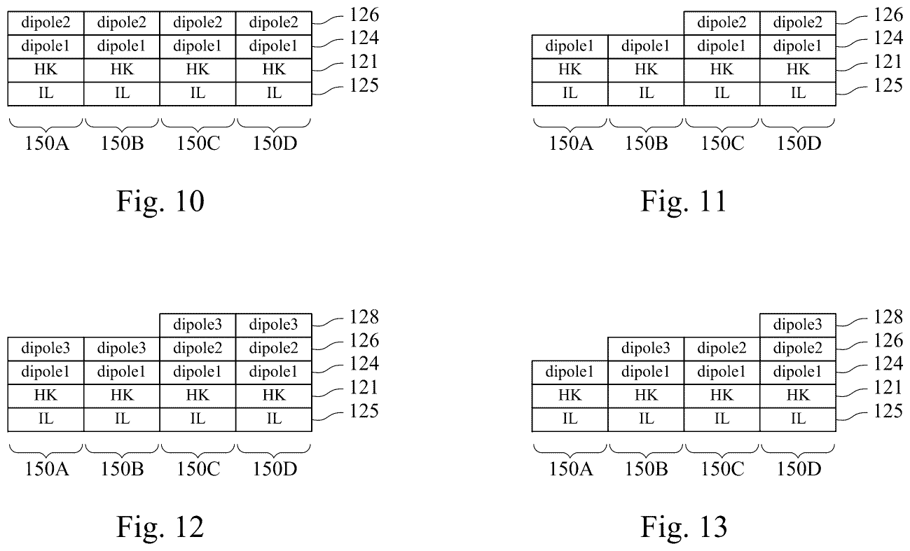

FIGS. 10, 11, 12, 13, 14, 15A and 15B illustrate subsequent processing steps for forming different dipoles in different portions of the gate dielectric material 121 located in gate trenches 103A, 103B, 103C, and 103D, such that different threshold voltages are achieved for gate stacks formed in the different gate trenches. For simplicity, FIGS. 10, 11, 12, 13, 14, 15A and 15B only illustrate portions of the NSFET device 100 formed in the regions 150A, 150B, 150C, and 150D.

Next, in FIG. 10, a dipole layer 126 is formed (e.g., conformally) in the regions 150A, 150B, 150C, and 150D on and around the dipole layer 124 using a same or similar formation method as the dipole layer 124. In some embodiments, the dipole layer 126 comprises a different type (e.g., n-type or p-type) of dipole-forming element than the dipole layer 124. For example, one of the dipole layers 124 and 126 comprises an n-type dipole-forming metal, and the other comprises a p-type dipole-forming metal. In some embodiments, the dipole layer 126 comprises the same type of dipole-forming element as the dipole layer 124, but the dipole-forming elements of the dipole layers 124 and 126 are two different materials. For example, one of the dipole-forming elements is La, the other is Y, and both are n-type dipole-forming metals. In some embodiments, the dipole layer 126 and the dipole layer 124 are formed of a same dipole material. For example, both dipole layers 124 and 126 are formed of La₂O₃.

Next, in FIG. 11, the dipole layer 126 is removed from the regions 150A and 150B. For example, a patterned mask layer, such as a patterned photoresist layer, is formed to cover the regions 150C and 150D and to expose the regions 150A and 150B. An etching process is then performed to remove the dipole layer 126 in the regions 150A and 150B. In embodiments where the dipole layers 124 and 126 are formed of different materials, a selective etching using an etchant selective to the material of the dipole layer 126 may be performed to remove the dipole layer 126. In embodiments where the dipole layers 124 and 126 are formed of a same material, a timed etch may be performed to stop the etching process after the dipole layer 126 is remove. The patterned mask layer is then removed using a suitable removal process, such as stripping or ashing.

Next, in FIG. 12, a dipole layer 128 is formed (e.g., conformally) in the regions 150A and 150B on and around the dipole layer 124, and is formed (e.g., conformally) in the regions 150C and 150D on and around the dipole layer 126, using a same or similar formation method as the dipole layer 124. The dipole layer 128 may comprise any suitable type (e.g., n-type or p-type) of dipole-forming element, and the dipole-forming element in the dipole layer 128 may be any suitable material. In some embodiments, one of the dipole layers 124, 126, and 128 comprises an n-type (or p-type) dipole-forming element, and the other two of the dipole layers 124, 126, and 128 comprise a p-type (or n-type) dipole-forming element. The two dipole layers comprising the same type of dipole-forming element may or may not be formed of the same material (e.g., La₂O₃). In some embodiments, the dipole layers 124, 126, and 128 comprise the same type (e.g., n-type or p-type) of dipole-forming elements, and the dipole-forming elements of the dipole layers 124, 126, and 128 may or may not be the same material. In an example, the dipole-forming elements of the dipole layers 124, 126, and 128 are the same (e.g., La). As another example, at least two of the dipole-forming elements of the dipole layers 124, 126, and 128 are the same. As yet another example, the dipole-forming elements of the dipole layers 124, 126, and 128 are all different from each other. In some embodiments, the thickness of each of the dipole layers 124, 126, and 128 is adjusted to a specific value (e.g., a different value), such that after the dipole drive-in process, the density of the diploe-forming element diffused from each of the dipole layers into the gate dielectric material 121 reach a respective target value.

Next, in FIG. 13, the dipole layer 128 is removed from the regions 150A and 150C. A patterned mask layer may be used to cover the regions 150B and 150D while exposing the regions 150A and 150C. An etching process is then performed to remove the dipole layer 128 from the regions 150A and 150C. Next, the patterned mask layer is removed using a suitable removal process. Details are the same as or similar to those discussed above for the dipole layer 126, thus not repeated.

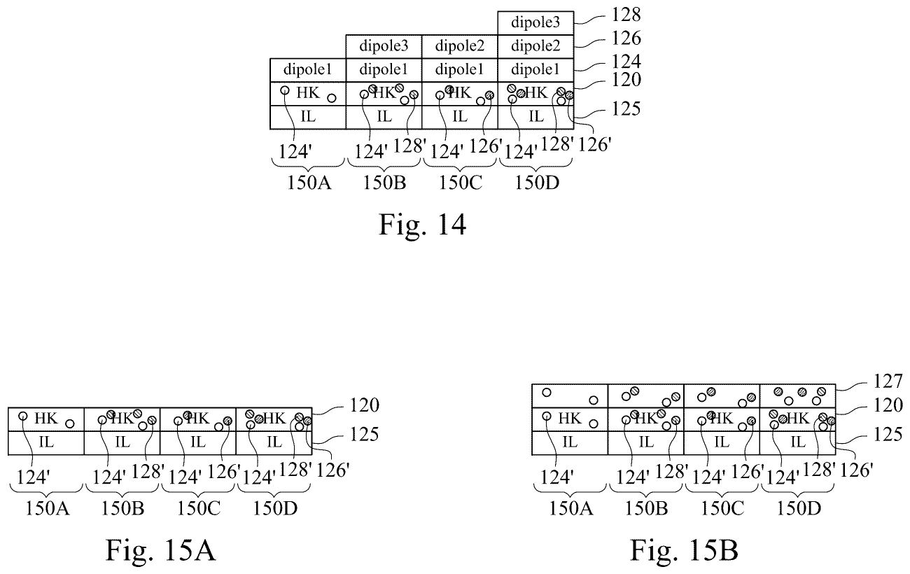

Next, in FIG. 14, the dipole drive-in process is preformed to drive the dipole-forming elements in the dipole layers 124, 126, and 128 into the gate dielectric layer 121. In an example embodiment, the dipole drive-in process is a thermal process performed at a temperature between about 500° C. and about 1000° C. FIG. 14 illustrates the dipole-forming elements 124′, 126′, and 128′ driven (e.g., diffused) into the gate dielectric material by the dipole drive-in process. In particular, the circular shapes labeled as 124′, 126′, and 128′ in FIG. 14 illustrate atoms of the dipole-forming elements 124′, 126′, and 128′ of the dipole layers 124, 126, and 128, respectively. In some embodiments, the amount of dipole-forming elements (e.g., 128′) driven into the gate dielectric material 120 decreases as the distance between the corresponding dipole layer (e.g., 128) and the gate dielectric material 120 increases. Therefore, more dipole-forming elements 128′ are driven into the gate dielectric material 120 in the region 150B than in the region 150D. Note that the number of the circular shapes illustrated in FIG. 14 is illustrative and non-limiting. The gate dielectric material 121 (see, e.g., FIG. 13) with the diffused dipole-forming elements 124′, 126′, and 128′ are referred to as gate dielectric material 120 hereinafter. As discussed above, the atoms of the dipole-forming elements 124′, 126′, and 128′ in the gate dielectric material 120 form diploes with atoms of certain element (e.g., oxygen atoms) of the gate dielectric material 120. For simplicity, the circular shapes labeled 124′, 126′, and 128′ in the gate dielectric material 120 are also used to indicate the dipoles formed by the dipole-forming elements 124′, 126′, and 128′, and the dipoles formed are not separately illustrated.

Next, in FIG. 15A, the dipole layers 124, 126, and 128 are removed from the gate trenches, e.g., by one or more etching processes. FIG. 15A illustrates the gate dielectric material 120 after the removal of the dipole layers 124, 126, and 128. As illustrated in FIG. 15A, the gate dielectric material 120 in different gate trenches, such as in the regions 150A, 150B, 150C, and 150D, includes different types of dipoles formed by the dipole-forming elements 124′, 126′, and 128′. Due to the different types of the dipoles formed and the different dipole orientations/dipole moments/dipole densities, the threshold voltages of the gate stacks formed subsequently in the gate trenches are different, in some embodiments.

In the example of FIG. 15A, after the etching process(es) to remove the dipole layers 124, 126, and 128, the gate dielectric material 120 is exposed. FIG. 15B illustrates another example where after the etching process(es) to remove the dipole layers 124, 126, and 128, residual portions of the dipole layers 124, 126, and 128 remain on the gate dielectric material 120 and form a dipole layer 127. In other words, the dipole layer 127 may be or include a mixture of the materials of the dipole layers 124, 126, and 128. Due to the dipole drive-in process performed previously, the dipole layer 127 also includes dipoles formed by the dipole-forming elements 124′, 126′, and 128′ from the dipole layers 124, 126, and 128. The number of dipole-forming elements illustrated in FIG. 15B is illustrative and not limiting. The thickness of the dipole layer 127 may be exaggerated in FIG. 15B. In some embodiments, the thickness of the dipole layer 127 is smaller than the thickness of the gate dielectric material 120, such as being less than 10% or 5% of the thickness of the gate dielectric material 120.

Since the dipole layers 124, 126, and 128 are removed after the dipole drive-in process, the disclosed method for forming dipoles in the gate dielectric material 120 has little or no impact on the space available in the gate trenches 103 for other layers of materials of the gate stacks. This illustrates an advantage over a reference method where dipole layers (e.g., 124, 126, and 128) are formed on the gate dielectric material 121 as part of the final gate structure formed (without being removed). Note that the dipole-forming element in the dipole layer forms dipoles in the dipole layer. For example, in a dipole layer formed of La₂O₃, the dipole-forming metal (e.g. La) form dipoles by forming bonds with oxygen atoms in the dipole layer. Therefore, one or more dipole layers may be formed as part of the gate stack to adjust the threshold voltage in the reference method. However, the one or more dipole layers formed over the gate dielectric material 121 take up space in the gate trench, which makes it difficult to form other layers (e.g., work function layers, gate electrode material) of the gate stack in the gate trench. This difficulty is especially pronounced for advanced semiconductor processing nodes due to the small width of the gate trench. The various embodiment methods disclosed herein for adjusting the thresholds voltages of the gate stacks overcome the above described difficulty of the reference method.

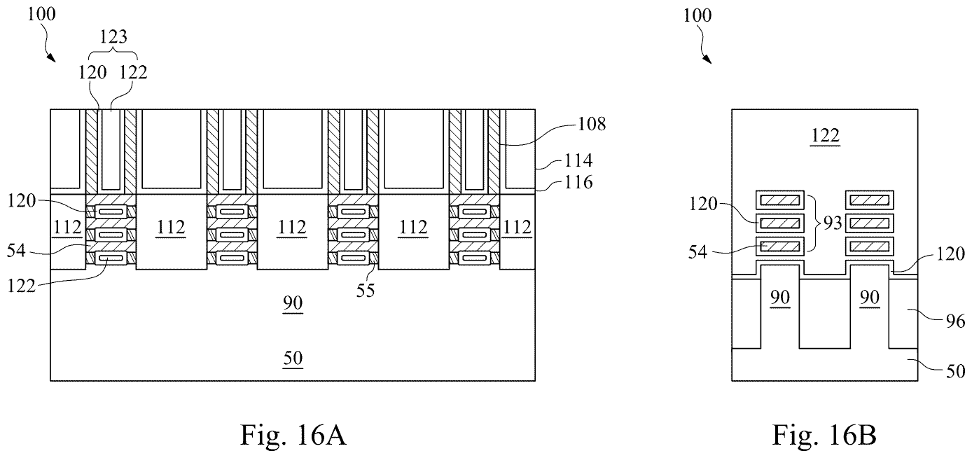

Next, in FIGS. 16A and 16B, a gate electrode material 122 is deposited over and around the gate dielectric material 120, and fills the remaining portions of the gate trenches 103. The gate electrode material 122 may include a metal-containing material such as TiN, TiO, TaN, TaC, Co, Ru, Al, W, combinations thereof, or multi-layers thereof. For example, although a single-layer gate electrode material 122 is illustrated, the gate electrode material 122 may comprise any number of liner layers (e.g., barrier layers), any number of work function tuning layers, and a fill material (e.g., a fill metal, an electrically conductive material). After the gate electrode material 122 is formed, a planarization process, such as a CMP, may be performed to remove excess portions of the gate dielectric material 120 and the gate electrode material 122, which excess portions are over the top surface of the first ILD 114. The remaining portions of the gate electrode material 122 and the gate dielectric material 120 thus form the gate electrodes 122 and the gate dielectric layers 120 of the replacement gate structures 123 of the resulting NSFET device 100, respectively. Each gate electrode 122 and the corresponding gate dielectric layer 120 may be collectively referred to as a gate stack, a replacement gate structure, a metal gate structure, or a gate structure. Each gate structure 123 extends around the respective nanostructures 54. In embodiments where the dipole layer 127 (see FIG. 15B) is formed, the gate structure 123 includes the dipole layer 127 between the gate dielectric layer 120 and the gate electrode 122.

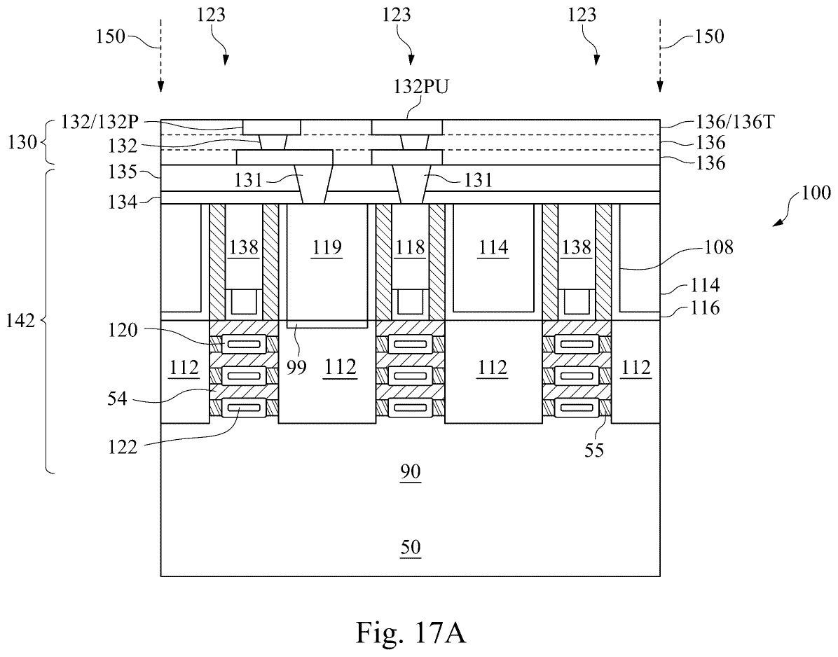

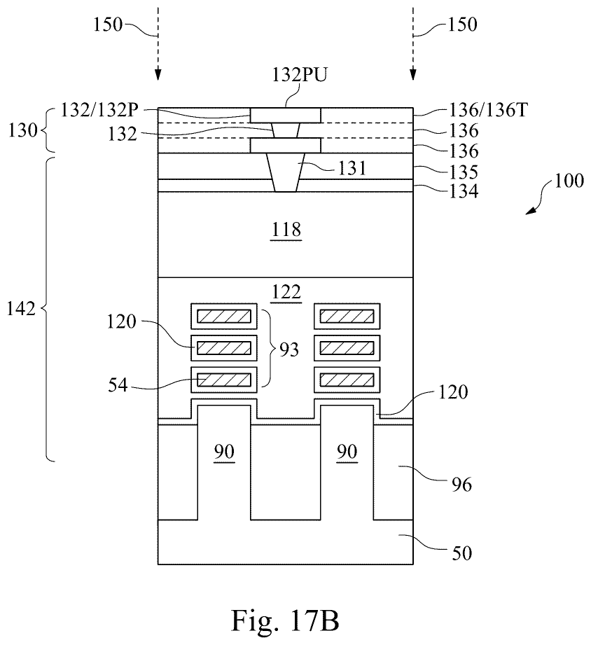

Next, in FIGS. 17A and 17B, gate masks 138 are formed over the replacement gate structures 123. The formation process of the gate masks 138 may include recessing replacement gate structures 123, filling the resulting recesses with a dielectric material such as silicon nitride, silicon carbonitride, silicon oxynitride, silicon oxycarbonitride, or the like, and performing a planarization process to remove excess portions of the dielectric material over the first ILD 114. The remaining portions of the dielectric material form the gate masks 138.

Next, source/drain contact plugs 119 and gate contact plugs 118 are formed to electrically couple to the source/drain regions 112 and the replacement gate structures 123, respectively. In the illustrated embodiments, the source/drain contact plugs 119 and the gate contact plugs 118 are formed in a self-aligned manner, and fill the spaces between opposing sidewalls of the CESL 116 and spaces between opposing sidewalls of the gate spacers 108, respectively.

In some embodiments, one or more anisotropic etching processes are performed to remove portions of the first ILD 114 and portions of the CESL 116 that are disposed over the source/drain regions 112 to form source/drain contact openings that expose the source/drain regions 112. Similar, one or more anisotropic etching processes may be performed to remove the gate masks 138 to form the gate contact openings that expose the replacement gate structures 123.

The source/drain contact plugs 119 and the gate contact plugs 118 may be formed by filling the source/drain contact openings and the gate contact openings with an electrically conductive material(s), such as tungsten, although other suitable materials such as aluminum, copper, tungsten nitride, rhuthenium, silver, gold, rhodium, molybdenum, nickel, cobalt, cadmium, zinc, alloys of these, combinations thereof, and the like, may alternatively be utilized. A planarization process, such as CMP, may be performed to remove excess portions of the electrically conducive material(s) that are disposed outside of the source/drain contact openings and the gate contact openings. The number and the location of the source/drain contact plugs 119 and the gate contact plugs 118 illustrated in the figures are illustrative and non-limiting, as skilled artisans readily appreciate.

In the illustrated embodiments, silicide regions 99 are formed on the source/drain regions 112 before the source/drain contact openings are filled to form the source/drain contact plugs 119. In some embodiments, the silicide regions 99 are formed by depositing a metal capable of reacting with semiconductor materials (e.g., silicon, germanium) to form silicide or germanide regions, such as nickel, cobalt, titanium, tantalum, platinum, tungsten, other noble metals, other refractory metals, rare earth metals or their alloys, over the source/drain regions 112, then performing a thermal anneal process to form the silicide regions 99. The un-reacted portions of the deposited metal are then removed, e.g., by an etching process. Although regions 99 are referred to as silicide regions, regions 99 may also be germanide regions, or silicon germanide regions (e.g., regions comprising silicide and germanide).

Next, an etch stop layer (ESL) 134 and a second ILD 135 are formed sequentially over, e.g., the first ILD 114, the replacement gate structures 123, and the gate spacers 108. The ESL 134 may include a dielectric material having a high etching selectivity from the etching of the second ILD 135, such as aluminum oxide, aluminum nitride, silicon oxycarbide, or the like, and may be formed using CVD, ALD, or the like. The second ILD 135 may be formed of PSG, BSG, BPSG, USG, or the like, which may be deposited by any suitable method, such as CVD, flowable CVD, PECVD, or the like.

Next, vias 131 are formed to extend through the second ILD 135 and the ESL 134, and to electrically couple to the source/drain contact plugs 119 and gate contact plugs 118. The vias 131 may be formed by forming via openings that extend through the second ILD 135 and the ESL 134, then filling the via openings with an electrically conductive material(s). The electrically conductive material(s) may be the same as or similar to those used for the source/drain contact plugs 119 or the gate contact plugs 118, thus details are not repeated. In some embodiments, a liner layer (e.g., a diffusion barrier layer) may be formed along sidewalls of the via openings before the electrically conductive material(s) fills the via openings. The liner layer may be titanium, tantalum, titanium nitride, tantalum nitride, or the like, and may be formed using any suitable formation methods, such as CVD, ALD, or the like.

In FIGS. 17A and 17B, the layers of the NSFET device 100 disposed between upper portions of the fins 90 and the second ILD 135 are collectively referred to as the device layer 142 of the NSFET device 100.

Still referring to FIGS. 17A and 17B, next, a front-side interconnect structure 130 is formed on the device layer 142. The front-side interconnect structure 130 includes dielectric layers 136 and layers of conductive features 132 in the dielectric layers 136. The dielectric layers 136 may include a suitable dielectric material, such as silicon oxide, silicon nitride, a low-K dielectric material, combinations therefore, or the like, and may be formed by any suitable formation method, such as CVD, PECVD, ALD, combinations thereof, or the like. The conductive features 132 (e.g., electrically conductive features) may include metal lines and vias, which may be formed using, e.g., damascene processes. The conductive features 132 may include diffusion barriers and a metal-containing material (e.g., copper) over the diffusion barriers. The diffusion barriers (may also be referred to as liner layers) may be, e.g., Ta, Ti, TaN, TiN, or the like. The metal-containing material may be, e.g., Cu, Co, Ru, Mo, or the like. In some embodiments, the topmost conductive features 132 (e.g., the conductive features 132 in a topmost dielectric layer 136T distal from the device layer 142) may include conductive features 132P (e.g., bonding pads, or metal patterns used for bonding) used for bonding with another semiconductor device. Therefore, the conductive features 132P may also be referred to as bonding features or bonding structures. Although not illustrated, a backside interconnect structure similar to the front-side interconnect structure 130 may be formed at the backside of the device layer 142.

In some embodiments, multiple NSFET devices 100 are formed on a wafer (e.g., a substrate 50). A dicing process may be performed along dicing regions indicated by the dashed lines 150 in FIGS. 17A and 17B to separate the multiple NSFET devices 100 into individual (e.g., separate) NSFET devices 100. Additional processing steps may be performed to complete the formation of the NSFET device 100, as skilled artisans readily appreciate, details are not discussed here.

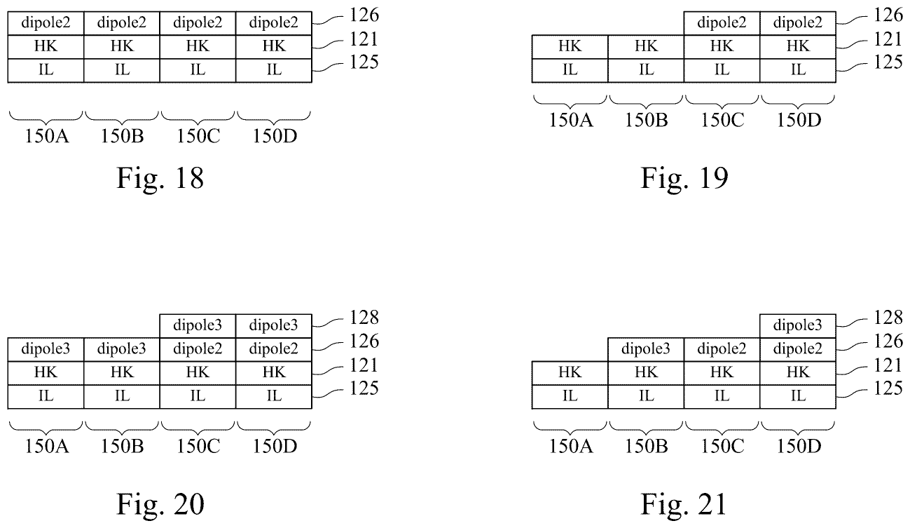

In FIGS. 9C, 10, 11, 12, 13, 14, 15A, and 15B, the dipole layer 124 is formed first (e.g., before dipole layers 126 and 128 are formed) and in all of the gate trenches, such as in regions 150A, 150B, 150C, and 150D. This embodiment process for forming different dipoles in the gate dielectric material 120 is referred to as a global dipole film first process. An alternative method for forming different dipoles in the gate dielectric material 120, referred to as global dipole film last process, is discussed below with reference to FIGS. 18, 19, 20, 21, 22, 23, and 24.

The processing in FIG. 18 follows the formation of the gate dielectric material 121 in FIGS. 9A and 9B. In other words, after forming the gate dielectric material 121 as illustrated in FIGS. 9A and 9B, the dipole layer 126 (instead of dipole layer 124) is formed on and around the gate dielectric material 121 in all of the gate trenches.

Next, in FIG. 19, the dipole layer 126 is removed from the gate trenches corresponding to the regions 150A and 150B. After removal of the dipole layer 126, the gate dielectric material 121 in the gate trenches corresponding to the regions 150A and 150B are exposed.

Next, in FIG. 20, the dipole layer 128 is formed in all of the gate trenches, such as over and around the gate dielectric material 121 in the regions 150A and 150B, and over and around the dipole layer 126 in the regions 150C and 150D.

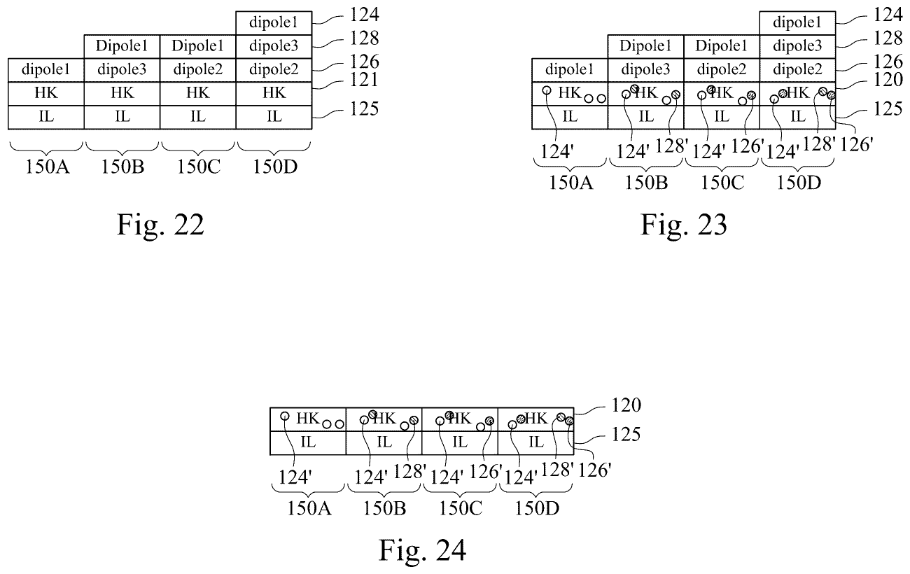

Next, in FIG. 21, the dipole layer 128 is removed from the gate trenches corresponding to the regions 150A and 150C. Next, in FIG. 22, the dipole layer 124 is formed in all of the gate trenches, such as in regions 150A, 150B, 150C, and 150D.

Next, in FIG. 23, the dipole drive-in process is performed to drive the dipole-forming elements 124′, 126′, and 128′ of the dipole layers 124, 126, and 128 into the gate dielectric material (labeled as 120 in FIG. 23), and the dipole-forming elements 124′, 126′, and 128′ form dipoles in the gate dielectric material 120. Recall that the amount of dipole elements driven into the gate dielectric material decreases as the distance between the corresponding dipole layer and the gate dielectric material increases. Therefore, in the example of FIG. 23, the dipole-forming element 124′ has the highest concentration in the region 150A, and has the lowest concentration in the region 150D. Similarly, the concentration of the dipole-forming element 128′ in the region 150B is higher than that in the region 150D. The concentration of the dipole-forming element 126′ in the regions 150C and 150D are the same. Due to the different dipoles and/or different dipole concentrations in different gate trenches, the threshold voltages of the gate stacks formed subsequently in the gate trenches may achieve different values.

Next, in FIG. 24, the dipole layers 124, 126, and 128 are removed, e.g., by one or more etching processes. In the embodiment of FIG. 24, the gate dielectric material 120 is exposed after the one or more etching process, same as or similar to FIG. 15A. In other embodiments, residual portions of the dipole layers 124, 126, and 128 remain on gate dielectric layer 120 and form a dipole layer 127, same as or similar to FIG. 15B, details are not repeated here.

After the dipole layers 124, 126, and 128 are removed, the gate electrode material 122 is formed to fill the gate trenches and to form the replacement gate structures 123, and additional processing (e.g., forming the front-side interconnect structure 130) may be performed to finish the fabrication of the NSFET device 100. The cross-section views of the NSFET device in these processing steps may be the same as or similar to FIGS. 16A, 16B, 17A, and 17B, thus not repeated.

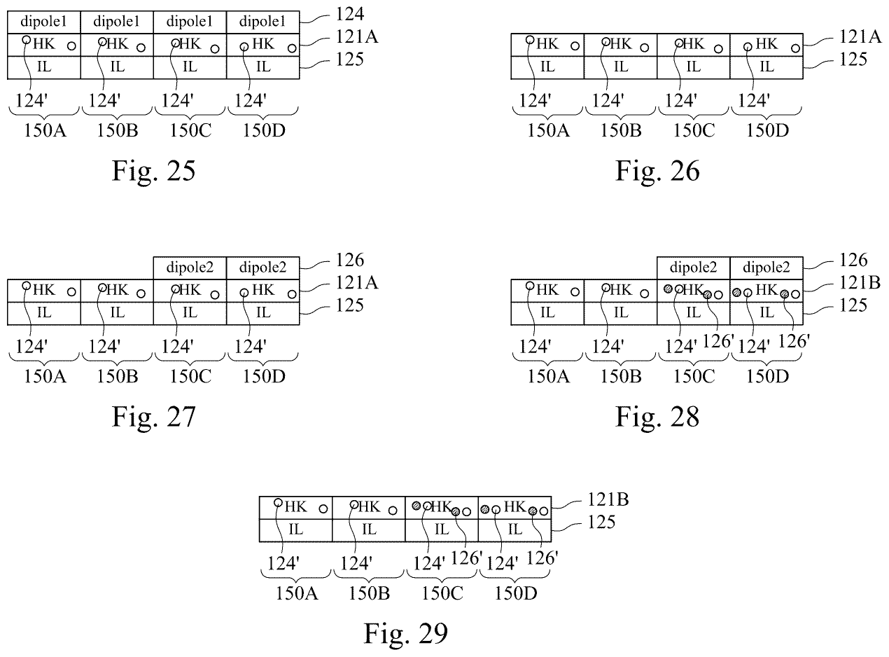

FIGS. 25, 26, 27, 28, 29, 30, 31, and 32 illustrate yet another embodiment method for forming different dipoles in the gate dielectric material 120 disposed in different gate trenches. The processing step of FIG. 25 follows the processing step of FIGS. 9A and 9B.

In FIG. 25, after the dipole layer 124 is formed in FIGS. 9A-9C in regions 150A, 150B, 150C, and 150D, a first dipole drive-in process (e.g., a first thermal process) is performed to drive the dipole-forming element 124′ of the dipole layer 124 into the gate dielectric material (labeled as 121A in FIG. 25 to indicate the incorporation of the dipole-forming element 124′ in the gate dielectric material 121). Next, in FIG. 26, the dipole layer 124 is removed from the regions 150A, 150B, 150C, and 150D, e.g., using a suitable etching process.

Next, in FIG. 27, the dipole layer 126 is formed in the regions 150A, 150B, 150C, and 150D. Next, the dipole layer 126 in the regions 150A and 150B is removed. Next, in FIG. 28, a second dipole drive-in process (e.g., a second thermal process) is performed to drive the dipole-forming element 126′ of the dipole layer 126 into the gate dielectric material (labeled as 121B in FIG. 28 to indicate the incorporation of the dipole-forming element 126′ in the gate dielectric material 121) in the regions 150C and 150D. Next, in FIG. 29, the dipole layer 126 is removed from the regions 150A, 150B, 150C, and 150D, e.g., using a suitable etching process.

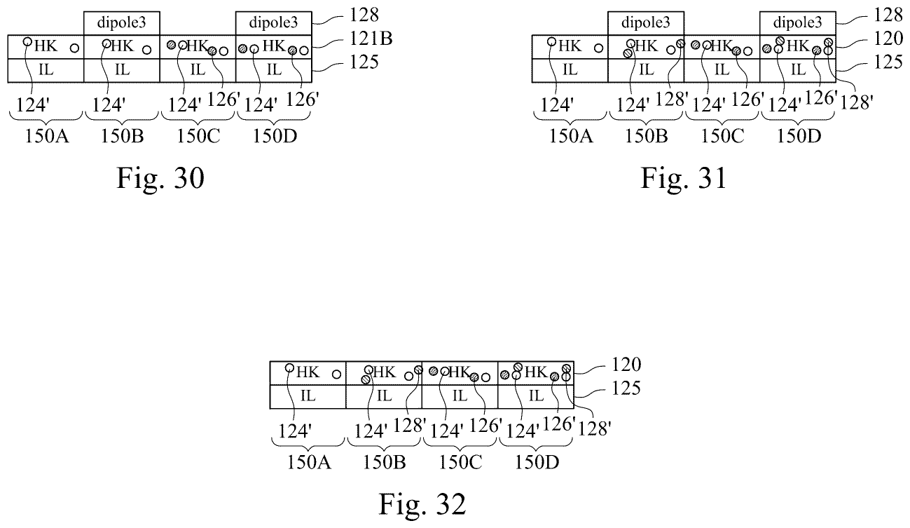

Next, in FIG. 30, the dipole layer 128 is formed in the regions 150A, 150B, 150C, and 150D. Next, the dipole layer 128 in the regions 150A and 150C is removed. Next, in FIG. 31, a third dipole drive-in process (e.g., a third thermal process) is performed to drive the dipole-forming element 128′ of the dipole layer 128 into the gate dielectric material (labeled as 120 in FIG. 31 to indicate the incorporation of the dipole-forming element 128′ in the gate dielectric material 121) in the regions 150B and 150D. Next, in FIG. 32, the dipole layer 128 is removed from the regions 150A, 150B, 150C, and 150D, e.g., using a suitable etching process.

Note that method illustrated in FIGS. 25-32 provides additional parameters for tuning the threshold voltages of the gate stacks. In particular, besides using dipole layers comprising different dipole-forming elements and/or having different thicknesses, the method illustrated in FIGS. 25-32 allows adjustment of the condition of each of the first dipole drive-in process, the second dipole drive-in process, and the third dipole drive-in process. For example, the temperature and the duration of each of the first, the second, and the third dipole drive-in process may be individually adjusted (e.g., to different values) to achieve a different concentration of the dipoles formed in the gate dielectric material 120 by the dipole-forming element of the respective dipole layer.

In the embodiment of FIG. 32, the gate dielectric material 120 is exposed after the etching process performed to remove the dipole layer 128, same as or similar to FIG. 15A. In other embodiments, residual portions of the dipole layers 124, 126, and 128 remain on the gate dielectric material 120 and form a dipole layer 127, same as or similar to FIG. 15B, details are not repeated here.

After the processing step of FIG. 32, the gate electrode material 122 is formed to fill the gate trenches 103 and to form the replacement gate structures 123, and additional processing (e.g., forming the front-side interconnect structure 130) may be performed to finish the fabrication of the NSFET device 100. The cross-section views of the NSFET device in these processing steps may be the same as or similar to FIGS. 16A, 16B, 17A, and 17B, thus not repeated.

Advantages are achieved by the disclosed embodiments. For example, by using different dipole layers comprising different dipole-forming elements and/or having different thicknesses, the disclosed embodiments allow easy tuning of the threshold voltages of different gate stacks. As a result, gate stacks formed in different regions of the semiconductor device may have different threshold voltages to meet different performance targets. One of the disclosed embodiments allows the process condition, such as temperature and the duration of process, for each of the dipole drive-in processes to be adjusted individually, thus providing more flexibility in the adjustment of the threshold voltages of different gate stacks. By removing the dipole layers after the dipole drive-in process(es), the disclosed embodiments do not reduce the space available for the gate electrode material in gate trenches, which is a significant advantage for advanced semiconductor processing nodes. The disclosed methods can be easily integrated into existing production flow for efficient and inexpensive implementation.

Modifications and variations to the disclosed embodiments are possible, and are fully intended to be included within the scope of the present disclosure. For example, three dipole layers 124, 126, 128 are used in the illustrated embodiments as non-limiting examples. Skilled artisans will readily appreciate that any suitable number of dipole layers (e.g., more or less than three dipole layers) may be used to adjust the threshold voltages of the gate stacks.

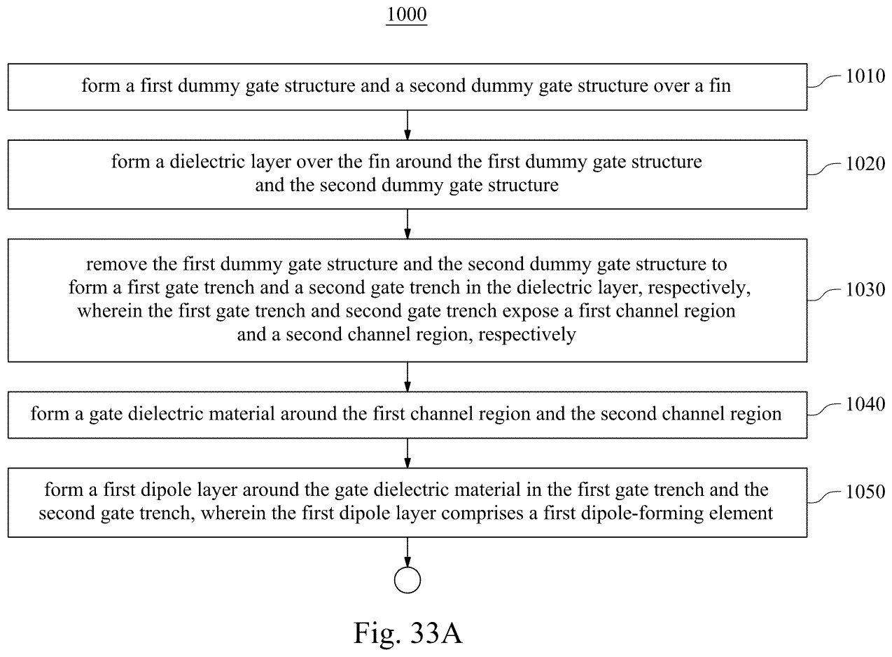

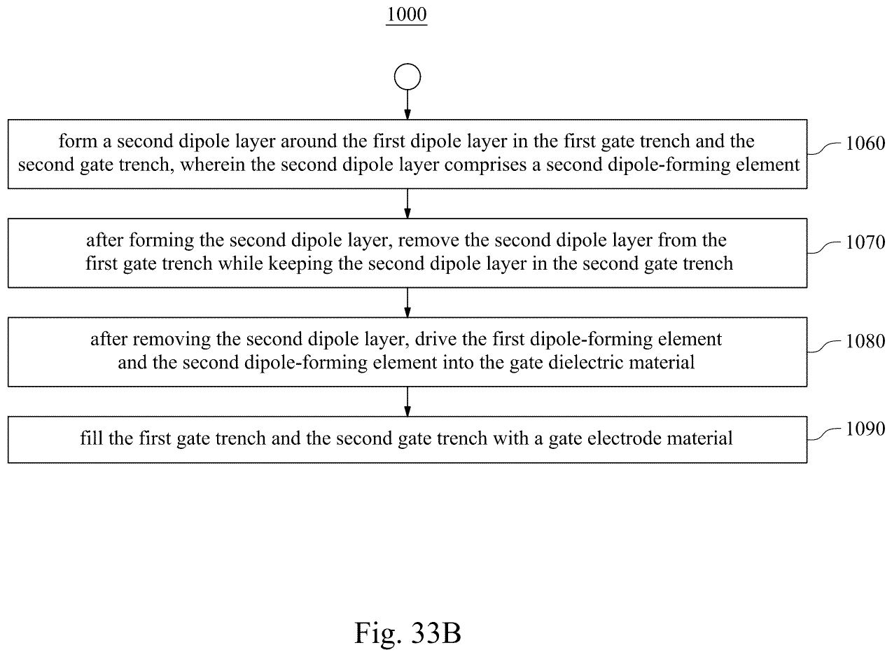

FIGS. 33A and 33B together illustrates a flow chart of a method 1000 of forming a semiconductor device, in accordance with some embodiments. It should be understood that the embodiment method shown in FIGS. 33A and 33B is merely an example of many possible embodiment methods. One of ordinary skill in the art would recognize many variations, alternatives, and modifications. For example, various steps as illustrated in FIGS. 33A and 33B may be added, removed, replaced, rearranged, or repeated.

Referring to FIGS. 33A and 33B, at block 1010, a first dummy gate structure and a second dummy gate structure are formed over a fin. At block 1020, a dielectric layer is formed over the fin around the first dummy gate structure and the second dummy gate structure. At block 1030, the first dummy gate structure and the second dummy gate structure are removed to form a first gate trench and a second gate trench in the dielectric layer, respectively, wherein the first gate trench and the second gate trench expose a first channel region and a second channel region, respectively. At block 1040, a gate dielectric material is formed around the first channel region and the second channel region. At block 1050, a first dipole layer is formed around the gate dielectric material in the first gate trench and the second gate trench, wherein the first dipole layer comprises a first dipole-forming element. At block 1060, a second dipole layer is formed around the first dipole layer in the first gate trench and the second gate trench, wherein the second dipole layer comprises a second dipole-forming element. At block 1070, after forming the second dipole layer, the second dipole layer is removed from the first gate trench while keeping the second dipole layer in the second gate trench. At block 1080, after removing the second dipole layer, the first dipole-forming element and the second dipole-forming element are driven into the gate dielectric material. At block 1090, the first gate trench and the second gate trench are filled with a gate electrode material.

In an embodiment, a method of forming a semiconductor device includes: forming a fin protruding above a substrate; forming a first dummy gate structure and a second dummy gate structure over the fin; forming an interlayer dielectric (ILD) layer over the fin around the first dummy gate structure and the second dummy gate structure; forming a first gate trench and a second gate trench in the ILD layer by removing the first dummy gate structure and the second dummy gate structure, respectively, wherein the first gate trench and the second gate trench expose a first channel region and a second channel region, respectively; forming a gate dielectric material around the first channel region and the second channel region; forming a first dipole material in the first gate trench and the second gate trench around the gate dielectric material, wherein the first dipole material comprises a first dipole-forming element; forming a second dipole material in the second gate trench around the first dipole material, wherein the second dipole material comprises a second dipole-forming element; performing a dipole drive-in process to drive the first dipole-forming element and the second dipole-forming element into the gate dielectric material; after performing the dipole drive-in process, removing the first dipole material and the second dipole material; and filling the first gate trench and the second gate trench with a gate electrode material to form a first replacement gate structure and a second replacement gate structure, respectively. In an embodiment, forming the second dipole material comprises: forming the second dipole material in the first gate trench and the second gate trench; and after forming the second dipole material in the first gate trench and the second gate trench, removing the second dipole material from the first gate trench while keeping the second dipole material in the second gate trench. In an embodiment, forming the gate dielectric material comprises forming a high-K gate dielectric material around the first channel region and the second channel region. In an embodiment, performing the dipole drive-in process comprises performing a thermal process, wherein the thermal process drives the first dipole-forming element of the first dipole material into the gate dielectric material in the first gate trench, and drives the first dipole-forming element of the first dipole material and the second dipole-forming element of the second dipole material into the gate dielectric material in the second gate trench. In an embodiment, the first dipole-forming element and the second dipole-forming element are both n-type dipole-forming elements or p-type dipole-forming elements. In an embodiment, a first one of the first dipole-forming element and the second dipole-forming element is an n-type dipole-forming element, and a second one of the first dipole-forming element and the second dipole-forming element is a p-type dipole-forming element. In an embodiment, the first dipole material is different from the second dipole material. In an embodiment, the method further comprises, before performing the dipole drive-in process, forming a third dipole material in the second gate trench around the second dipole material. In an embodiment, the third dipole material and the second dipole material are a same material. In an embodiment, the first dipole-forming element is a first diploe-forming metal, and the second dipole-forming element is a second diploe-forming metal, wherein after performing the dipole drive-in process, the first diploe-forming metal and an element of the gate dielectric material form a first type of dipoles in the gate dielectric material, and the second diploe-forming metal and the element of the gate dielectric material form a second type of dipoles in the gate dielectric material. In an embodiment, the first type of dipoles achieves a first threshold voltage for the first replacement gate structure, wherein the first type of dipoles and the second type of dipoles achieve a second threshold voltage for the second replacement gate structure, wherein the first threshold voltage is different from the second threshold voltage.

In an embodiment, a method of forming a semiconductor device includes: forming a first dummy gate structure and a second dummy gate structure over a fin; forming a dielectric layer over the fin around the first dummy gate structure and the second dummy gate structure; removing the first dummy gate structure and the second dummy gate structure to form a first gate trench and a second gate trench in the dielectric layer, respectively, wherein the first gate trench and the second gate trench expose a first channel region and a second channel region, respectively; forming a gate dielectric material around the first channel region and the second channel region; forming a first dipole layer around the gate dielectric material in the first gate trench and the second gate trench, wherein the first dipole layer comprises a first dipole-forming element; forming a second dipole layer around the first dipole layer in the first gate trench and the second gate trench, wherein the second dipole layer comprises a second dipole-forming element; after forming the second dipole layer, removing the second dipole layer from the first gate trench while keeping the second dipole layer in the second gate trench; after removing the second dipole layer, driving the first dipole-forming element and the second dipole-forming element into the gate dielectric material; and filling the first gate trench and the second gate trench with a gate electrode material. In an embodiment, the first dipole-forming element is the same as the second dipole-forming element. In an embodiment, a first one of the first dipole-forming element and the second dipole-forming element is an n-type dipole-forming element, and a second one of the first dipole-forming element and the second dipole-forming element is a p-type dipole-forming element. In an embodiment, the method further comprises, after removing the second dipole layer and before the driving: forming a third dipole layer around the first dipole layer in the first gate trench and around the second dipole layer in the second gate trench; and after forming the third dipole layer, removing the third dipole layer from the second gate trench while keeping the third dipole layer in the first gate trench. In an embodiment, the first dipole-forming element is different from the second dipole-forming element, wherein the third dipole layer comprises the second dipole-forming element. In an embodiment, the method further comprises, after removing the second dipole layer and before the driving: forming a third dipole layer around the first dipole layer in the first gate trench and around the second dipole layer in the second gate trench, wherein the third dipole layer and the second dipole layer are formed of a same material, wherein the driving comprises performing a thermal process to drive the first dipole-forming element and the second dipole-forming element from the first, the second, and the third dipole layers into the gate dielectric material.

In an embodiment, a semiconductor device includes: a substrate; a fin protruding above the substrate; a first channel region over the fin; and a first gate structure over the fin around the first channel region, wherein the first gate structure comprises: a first gate dielectric layer around the first channel region, wherein the first gate dielectric layer comprises a high-K dielectric material, a first type of di-dipoles, and a second type of dipoles; and a gate electrode material around the first gate dielectric layer. The semiconductor device further includes: a second channel region over the fin; a second gate structure over the fin around the second channel region, the second gate structure being adjacent to the first gate structure, wherein the second gate structure comprises: a second gate dielectric layer around the second channel region, wherein the second gate dielectric layer comprises the high-K dielectric material and the first type of dipoles, wherein the second gate dielectric layer is free of the second type of dipoles; and the gate electrode material around the second gate dielectric layer. In an embodiment, the first type of dipoles are n-type dipoles, and the second type of dipoles are p-type dipoles. In an embodiment, a first threshold voltage of a first transistor comprising the first gate structure is different from a second threshold voltage of a second transistor comprising the second gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of forming a semiconductor device, the method comprising:
forming a fin protruding above a substrate;
forming a first dummy gate structure and a second dummy gate structure over the fin;
forming an interlayer dielectric (ILD) layer over the fin around the first dummy gate structure and the second dummy gate structure;
forming a first gate trench and a second gate trench in the ILD layer by removing the first dummy gate structure and the second dummy gate structure, respectively, wherein the first gate trench and the second gate trench expose a first channel region and a second channel region, respectively;
forming a gate dielectric material around the first channel region and the second channel region;
forming a first dipole material in the first gate trench and the second gate trench around the gate dielectric material, wherein the first dipole material comprises a first dipole-forming element;
forming a second dipole material in the second gate trench around the first dipole material, wherein the second dipole material comprises a second dipole-forming element;
performing a dipole drive-in process to drive the first dipole-forming element and the second dipole-forming element into the gate dielectric material;
after performing the dipole drive-in process, removing the first dipole material and the second dipole material; and
filling the first gate trench and the second gate trench with a gate electrode material to form a first replacement gate structure and a second replacement gate structure, respectively.

2. The method of claim 1, wherein forming the second dipole material comprises:
forming the second dipole material in the first gate trench and the second gate trench; and
after forming the second dipole material in the first gate trench and the second gate trench, removing the second dipole material from the first gate trench while keeping the second dipole material in the second gate trench.

3. The method of claim 1, wherein forming the gate dielectric material comprises forming a high-K gate dielectric material around the first channel region and the second channel region.

4. The method of claim 3, wherein performing the dipole drive-in process comprises performing a thermal process, wherein the thermal process drives the first dipole-forming element of the first dipole material into the gate dielectric material in the first gate trench, and drives the first dipole-forming element of the first dipole material and the second dipole-forming element of the second dipole material into the gate dielectric material in the second gate trench.

5. The method of claim 4, wherein the first dipole-forming element and the second dipole-forming element are both n-type dipole-forming elements or p-type dipole-forming elements.

6. The method of claim 4, wherein a first one of the first dipole-forming element and the second dipole-forming element is an n-type dipole-forming element, and a second one of the first dipole-forming element and the second dipole-forming element is a p-type dipole-forming element.

7. The method of claim 1, wherein the first dipole material is different from the second dipole material.

8. The method of claim 7, further comprising, before performing the dipole drive-in process, forming a third dipole material in the second gate trench around the second dipole material.

9. The method of claim 8, wherein the third dipole material and the second dipole material are a same material.

10. The method of claim 1, wherein the first dipole-forming element is a first diploe-forming metal, and the second dipole-forming element is a second diploe-forming metal, wherein after performing the dipole drive-in process, the first diploe-forming metal and an element of the gate dielectric material form a first type of dipoles in the gate dielectric material, and the second diploe-forming metal and the element of the gate dielectric material form a second type of dipoles in the gate dielectric material.

11. The method of claim 10, wherein the first type of dipoles achieves a first threshold voltage for the first replacement gate structure, wherein the first type of dipoles and the second type of dipoles achieve a second threshold voltage for the second replacement gate structure, wherein the first threshold voltage is different from the second threshold voltage.

12. A method of forming a semiconductor device, the method comprising:
forming a first dummy gate structure and a second dummy gate structure over a fin;
forming a dielectric layer over the fin around the first dummy gate structure and the second dummy gate structure;
removing the first dummy gate structure and the second dummy gate structure to form a first gate trench and a second gate trench in the dielectric layer, respectively, wherein the first gate trench and the second gate trench expose a first channel region and a second channel region, respectively;
forming a gate dielectric material around the first channel region and the second channel region;
forming a first dipole layer around the gate dielectric material in the first gate trench and the second gate trench, wherein the first dipole layer comprises a first dipole-forming element;
forming a second dipole layer around the first dipole layer in the first gate trench and the second gate trench, wherein the second dipole layer comprises a second dipole-forming element;
after forming the second dipole layer, removing the second dipole layer from the first gate trench while keeping the second dipole layer in the second gate trench;
after removing the second dipole layer, driving the first dipole-forming element and the second dipole-forming element into the gate dielectric material; and
filling the first gate trench and the second gate trench with a gate electrode material.

13. The method of claim 12, wherein the first dipole-forming element is the same as the second dipole-forming element.

14. The method of claim 12, wherein a first one of the first dipole-forming element and the second dipole-forming element is an n-type dipole-forming element, and a second one of the first dipole-forming element and the second dipole-forming element is a p-type dipole-forming element.

15. The method of claim 12, further comprising, after removing the second dipole layer and before the driving:
forming a third dipole layer around the first dipole layer in the first gate trench and around the second dipole layer in the second gate trench; and
after forming the third dipole layer, removing the third dipole layer from the second gate trench while keeping the third dipole layer in the first gate trench.

16. The method of claim 15, wherein the first dipole-forming element is different from the second dipole-forming element, wherein the third dipole layer comprises the second dipole-forming element.

17. The method of claim 12, further comprising, after removing the second dipole layer and before the driving:
forming a third dipole layer around the first dipole layer in the first gate trench and around the second dipole layer in the second gate trench, wherein the third dipole layer and the second dipole layer are formed of a same material, wherein the driving comprises performing a thermal process to drive the first dipole-forming element and the second dipole-forming element from the first, the second, and the third dipole layers into the gate dielectric material.

18. A semiconductor device comprising:
a substrate;
a fin protruding above the substrate;
a first channel region over the fin;
a first gate structure over the fin around the first channel region, the first gate structure comprising:
a first gate dielectric layer around the first channel region, wherein the first gate dielectric layer comprises a high-K dielectric material, a first type of di-dipoles, and a second type of dipoles; and
a gate electrode material around the first gate dielectric layer;
a second channel region over the fin;
a second gate structure over the fin around the second channel region, the second gate structure being adjacent to the first gate structure, the second gate structure comprising:
a second gate dielectric layer around the second channel region, wherein the second gate dielectric layer comprises the high-K dielectric material and the first type of dipoles, wherein the second gate dielectric layer is free of the second type of dipoles; and
the gate electrode material around the second gate dielectric layer.

19. The semiconductor device of claim 18, wherein the first type of dipoles are n-type dipoles, and the second type of dipoles are p-type dipoles.

20. The semiconductor device of claim 18, wherein a first threshold voltage of a first transistor comprising the first gate structure is different from a second threshold voltage of a second transistor comprising the second gate structure.
